(19) United States
(12) Patent Application Publication
(10) Pub. No.: US 2013/0037103 A1
(43) Pub. Date: Feb. 14, 2013

(54) BACK SHEET FOR SOLAR CELL MODULE AND SOLAR CELL MODULE

(71) Applicant: Asahi Glass Company, Limited, Chiyoda-ku (JP)

(72) Inventors: Takashi NAKANO, Chiyoda-ku (JP); Naoko SHIROTA, Chiyoda-ku (JP)

(73) Assignee: Asahi Glass Company, Limited, Chiyoda-ku (JP)

(21) Appl. No.: 13/652,924

(22) Filed: Oct. 16, 2012

Related U.S. Application Data
(63) Continuation of application No. PCT/JP2011/059306, filed on Apr. 14, 2011.

(30) Foreign Application Priority Data
Apr. 16, 2010 (JP) 2010-095210

(51) Int. Cl. B32B 27/24; B05D 5/00; H01L 31/0203

(52) U.S. Cl. 136/256; 428/421; 427/74

(57) ABSTRACT

To provide a back sheet for a solar cell module, which is light in weight and excellent in productivity, wherein a coating film formed from a coating composition containing a fluorinated copolymer (A), which is formed on at least one side of a substrate sheet, is excellent in adhesion to the substrate and free from a problem of cracking, fracturing, whitening or peeling. A back sheet for a solar cell module, comprising a substrate sheet and, as formed on at least one side of the substrate sheet, a coating film formed from a coating composition containing a fluorinated copolymer (A); and a solar cell module using such a back sheet.

### TECHNICAL FIELD

The present invention relates to a back sheet for a solar cell module, and a solar cell module having the back sheet.

### BACKGROUND ART

A solar cell module is composed of a surface layer, a sealing material layer which seals a solar cell, and a back sheet. As a sealing material to constitute the sealing material layer, an ethylene/vinyl acetate copolymer (hereinafter referred to as EVA) is commonly used.

The back sheet is required to have various characteristics such as mechanical strength, weatherability, water/moisture-proof property and electrical insulation property. A common back sheet has a multilayer structure, and is, for example, composed of, sequentially from the side in contact with the sealing material layer of a solar cell, an electrical insulation layer, a water/moisture-proof layer and a rear surface layer which is located at the rear side of the solar cell.

Usually, a film of polyvinyl fluoride is used for the electrical insulation layer and the rear surface layer for the reason of e.g. excellent weatherability, water/moisture-proof property and electrical insulation property, and a polyethylene terephthalate (ethylene glycol/terephthalic acid copolymer, hereinafter referred to as PET) film is used for a substrate sheet. Further, in the case where a back sheet is required to have a high water/moisture-proof effect, a vapor-deposited layer of a metal oxide such as silica or a metal layer such as an aluminum foil is provided on the substrate sheet.

The thickness of the back sheet is commonly adjusted to be from 20 to 100 μm so that the above required properties and other required properties such as durability and light blocking property are satisfied. However, in recent years, the back sheet is required to be made lighter and thinner.

The present inventors considered that the film of polyvinyl fluoride used for the electric insulating layer and the rear surface layer of the back sheet had a disadvantage in making the back sheet lighter and thinner because such a film needs to be adhered to an PET film and further to have an adhesion layer. Further, there was a problem that the production process was complicated.

A back sheet of a solar cell module wherein a cured coating film of a curable functional group-containing fluoropolymer coating material is formed on at least one surface of a water-impermeable sheet, is proposed (Patent Document 1). This document discloses a curable tetrafluoroethylene (TFE) copolymer (ZEFFLE GK-570, trademark of Daikin Industries, Ltd.) as the curable functional group-containing fluoropolymer. However, it was found that the cured coating film of the curable functional group-containing fluoropolymer is insufficient in flexibility of the coating film, adhesion to a substrate and folding endurance property, and therefore problems such as cracking, fracturing, whitening and peeling occur, and that it has low dispersibility of a pigment or a curing agent, and therefore there are problems such as color shading due to poor dispersibility of the pigment and insufficient curing due to poor dispersibility of the curing agent.

### PRIOR ART DOCUMENT

### Patent Document

Patent Document 1: JP-A-2007-035694

### DISCLOSURE OF INVENTION

### Technical Problem

The present invention is to provide, by forming a coating film of a specific fluorinated copolymer (A) on at least one side of a substrate sheet, a back sheet for solar cell module, which is excellent in adhesion of the coating film to the substrate and free from a problem of cracking or fracturing and which is light in weight and excellent in productivity.

### Solution to Problem

As a result of an extensive study, the present inventors have found that a coating film of a coating composition containing a specific fluorinated copolymer (A) as an essential component, which is formed on at least one side of a substrate sheet, is excellent particularly in the flexibility of the coating film and in the adhesion to the substrate and have accomplished the present invention.

That is, the present invention provides the following [1] to [11].
[1] A back sheet for a solar cell module, comprising a substrate sheet and, as formed on at least one side of the substrate sheet, a coating film formed from a coating composition which comprises a fluorinated copolymer (A) having repeating units derived from ethylene and repeating units derived from tetrafluoroethylene, and a solvent capable of dissolving the fluorinated copolymer (A) at a temperature of not higher than the melting point of the fluorinated copolymer (A).
[2] The back sheet for a solar cell module according to [1], wherein the fluorinated copolymer (A) in the coating composition is one obtained by precipitating it from a solution having the fluorinated copolymer (A) dissolved in the solvent.
[3] The back sheet for a solar cell module according to [1] or [2], wherein the proportion of repeating units derived from monomers other than tetrafluoroethylene and ethylene, is from 0.1 to 30 mol % in all repeating units in the fluorinated copolymer (A).
[4] The back sheet for a solar cell module according to any one of [1] to [3], wherein the fluorinated copolymer (A) is a fluorinated copolymer having crosslinkable groups.
[5] The back sheet for a solar cell module according to [4], wherein the crosslinkable groups are at least one member selected from the group consisting of carboxy groups, acid anhydride groups and carboxylic halide groups.
[6] The back sheet for a solar cell module according to any one of [1] to [5], wherein, of the solvent, the dissolution index (R) for the fluorinated copolymer (A), based on Hansen solubility parameters and represented by the following formula (1), is less than 25:

R=4×(δd−15.7)²+(δp−5.7)²+(δh−4.3)² (1)

wherein δd, δp and δh represent the dispersion component, the polar component and the hydrogen bonding component, respectively, in Hansen solubility parameters, and their units are (MPa)^{1/2}, respectively.
[7] The back sheet for a solar cell module according to any one of [1] to [6], wherein the coating composition contains an ultraviolet absorber.
[8] The back sheet for a solar cell module according to any one of [1] to [6], wherein the coating composition contains a pigment.
[9] The back sheet for a solar cell module according to any one of [1] to [8], wherein a layer made of a polymer different from the coating film is provided on the outermost surface of the back sheet on the side to be in contact with a solar cell.
[10] A process for producing a back sheet for a solar cell module, which comprises applying a coating composition having a fluorinated copolymer (A) having repeating units derived from ethylene and repeating units derived from tetrafluoroethylene, dissolved in a solvent capable of dissolving the fluorinated copolymer (A) at a temperature of not higher than the melting point of the fluorinated copolymer (A), on at least one side of a substrate sheet, followed by removing the solvent to form a coating film.
[11] A solar cell module comprising, as sequentially laminated, a surface sheet, a sealing layer having a solar cell sealed by a resin, and the back sheet for a solar cell module as defined in any one of [1] to [9].

### Advantageous Effects of Invention

According to the present invention, by providing a coating film formed of the coating composition containing the specific fluorinated copolymer (A) on at least one side of the substrate sheet, it is possible to obtain a back sheet for a solar cell module, which is excellent particularly in adhesion of the coating film to the substrate and free from cracking or fracturing and which is light in weight and excellent in productivity. Further, it is possible to obtain a solar cell module provided with such a back sheet.

### BRIEF DESCRIPTION OF DRAWINGS

FIG. 1 is a cross-sectional view of an embodiment of the solar cell module of the present invention.

FIG. 2 is a cross-sectional view of an embodiment of the solar cell module of the present invention, wherein a metal layer is provided.

FIG. 3 is a cross-sectional view of an embodiment of the solar cell module of the present invention, wherein a EVA layer is provided.

### DESCRIPTION OF EMBODIMENTS

In this description, repeating units which are directly obtained by polymerization and repeating units which are obtained by further reacting the repeating units directly obtained by polymerization are collectively referred to as “units”.

The back sheet for a solar cell module of the present invention (hereinafter sometimes simply referred to as “a back sheet”) is characterized in that a coating film of a coating material prepared from a coating composition containing a fluorinated copolymer (A) (hereinafter sometimes simply referred to as “a coating composition”) is formed on at least one side of a substrate sheet.

### [Fluorinated Copolymer (A)]

The fluorinated copolymer (A) is not particularly limited so long as it is a fluorinated copolymer (A) comprising repeating units derived from ethylene and repeating units derived from tetrafluoroethylene. An example of such a fluorinated copolymer may specifically be e.g. ETFE having repeating units derived from ethylene and repeating units derived from tetrafluoroethylene (hereinafter sometimes referred to as “TFE”) as the main repeating units in the copolymer. Here, in this specification, the term “ETFE” is used as a general term for a fluorinated copolymer containing TFE and ethylene as the main repeating units in the copolymer, which may contain repeating units derived from comonomers other than TFE and ethylene, as the constituting units of the copolymer.

In the present invention, the fluorinated copolymer (A) may be one wherein the molar ratio of repeating units derived from TFE/repeating units derived from ethylene is preferably from 70/30 to 30/70, more preferably 65/35 to 40/60, most preferably from 60/40 to 40/60.

Further, in the fluorinated copolymer (A) in the present invention, in order to impart various functions to the obtainable copolymer, it is preferred that repeating units derived from comonomers other than TFE and ethylene are contained in addition to TFE and ethylene. Such comonomers to be used together with TFE and ethylene may be a monomer having no crosslinkable group (hereinafter referred to as a “non-crosslinkable monomer”) and a monomer having a crosslinkable group (hereinafter referred to as a “crosslinkable monomer”). The crosslinkable group may contribute to the adhesion to the substrate in a case where it is chemically bonded to the substrate or has an interaction by e.g. hydrogen bonding.

The non-crosslinkable monomer may, for example, be a fluoroethylene (provided that TFE is excluded) such as CF₂═CFCl or CF₂═CH₂; a fluoropropylene such as CF₂═CFCF₃, CF₂═CHCF₃ or CH₂═CHCF₃; a polyfluoroalkylethylene having a C₂₋₁₂ fluoroalkyl group, such as CF₃CF₂CH═CH₂, CF₃CF₂CF₂CF₂CH═CH₂, CF₃CF₂CF₂CF═CH₂, CF₃CF₂CF₂CF₂CF═CH₂ or CF₂HCF₂CF₂CF═CH₂; a perfluorovinyl ether such as R^{f} (OCFXCF₂)ₘOCF═CF₂ (wherein R^{f} is a C₁₋₆ perfluoroalkyl group, X is a fluorine atom or a trifluoromethyl group, and m is an integer of from 0 to 5); an olefin (provided that ethylene is excluded) such as a C3 olefin having three carbon atoms such as propylene, a C4 olefin having four carbon atoms such as butylene or isobutylene, 4-methyl-1-pentene, cyclohexene, styrene, or a-methylstyrene; a vinyl ester such as vinyl acetate, vinyl lactate, vinyl butyrate, vinyl pivalate or vinyl benzoate; an allyl ester such as allyl acetate; a vinyl ether such as methyl vinyl ether, ethyl vinyl ether, butyl vinyl ether, isobutyl vinyl ether, tert-butyl vinyl ether or cyclohexyl vinyl ether; a (meth)acrylic acid ester such as methyl (meth)acrylate, ethyl (meth)acrylate, n-butyl (meth)acrylate, isobutyl (meth)acrylate or cyclohexyl (meth)acrylate; or a chloroolefin such as vinyl chloride or vinylidene chloride.

Among these monomers, a fluoroolefin, particularly CF₂═CH₂, is preferred with a view to improving the solubility of the fluorinated copolymer (A) in a solvent. Further, with a view to improving the toughness or stress cracking resistance of the fluorinated copolymer, a polyfluoroalkylethylene, particularly CF₃CF₂CF₂CF₂CH═CH₂, is preferred.

These non-crosslinkable monomers may be used alone or in combination of two or more of them.

The crosslinkable group which the crosslinkable monomer has, may, for example, be a hydroxy group, a carboxylic acid group, a residue obtained by dehydration condensation of two carboxy groups in one molecule (hereinafter referred to as an “acid anhydride group”), a sulfonic acid group, an epoxy group, a cyano group, a carbonate group, an isocyanate group, an ester group, an amide group, an aldehyde group, an amino group, a hydrolyzable silyl group, a carbon-carbon double bond, or a carboxylic halide group. The above carboxylic acid group means a carboxy group or its salt (—COOM¹: M¹ is a metal atom or atomic group capable of forming a salt with a carboxylic acid), and the sulfonic acid group means a sulfo group or its salt (—SO₃M²: M² is a metal atom or atomic group capable of forming a salt with a sulfonic acid).

Most preferred is at least one member selected from the group consisting of a hydroxy group, a carboxylic acid group, an acid anhydride group and a carboxylic halide group.

The crosslinkable monomer may, for example, be a monomer having a hydroxy group, an acid anhydride, a monomer having a carboxy group or a monomer having an epoxy group.

The monomer having a hydroxy group may, for example, be a hydroxy group-containing vinyl ether such as 2-hydroxyethyl vinyl ether, 3-hydroxypropyl vinyl ether, 2-hydroxy-2-methylpropyl vinyl ether, 4-hydroxybutyl vinyl ether, 4-hydroxy-2-methylbutyl vinyl ether, 5-hydroxypentyl vinyl ether or 6-hydroxyhexyl vinyl ether; or a hydroxy group-containing allyl ether such as 2-hydroxyethyl allyl ether, 4-hydroxybutyl allyl ether or glycerol monoallyl ether. Among them, a hydroxy group-containing vinyl ether, particularly 4-hydroxybutyl vinyl ether or 2-hydroxyethyl vinyl ether, is more preferred from the viewpoint of the availability, polymerization reactivity and excellent crosslinkability of the crosslinkable group.

The acid anhydride may, for example, be itaconic anhydride, maleic anhydride, citraconic anhydride, or 5-norbornene-2,3-dicarboxylic anhydride. Among them, itaconic anhydride is preferred. The monomer having a carboxy group may, for example, be an unsaturated monocarboxylic acid such as acrylic acid, methacrylic acid, vinyl acetic acid, crotonic acid, cinnamic acid, undecylenic acid, 3-allyloxypropionic acid, 3-(2-allyloxyethoxycarbonyl)propionic acid or vinyl phthalate; an unsaturated dicarboxylic acid such as maleic acid, fumaric acid or itaconic acid; or an unsaturated dicarboxylic acid ester such as an itaconic acid monoester, a maleic acid monoester or a fumaric acid monoester. The monomer having an epoxy group may be a monomer having an epoxy group, such as glycidyl vinyl ether or glycidyl allyl ether.

Among them, a monomer having a hydroxy group, or an acid anhydride, is preferred with a view to obtaining a coating film having a high hardness or with a view to increasing the adhesion to the substrate.

These crosslinkable monomers may be used alone or in combination as a mixture of two or more of them. That is, two or more different types of crosslinkable groups may be present in one molecule of the fluorinated copolymer (A).

In a case where the fluorinated copolymer (A) contains units derived from a crosslinkable monomer, their content is preferably from 0.1 to 10 mol %, more preferably from 0.1 to 5 mol %, based on all monomer repeating units in the fluorinated copolymer (A).

In a case where the above fluorinated copolymer (A) contains repeating units derived from such comonomers other than TFE and ethylene, the total of their contents is preferably from 0.1 to 30 mol %, more preferably from 0.1 to 25 mol %, further preferably from 0.1 to 20 mol %, most preferably from 0.1 to 15 mol %, based on all monomer repeating units in the fluorinated copolymer (A). Further, depending upon the purpose of e.g. further improving the solubility, the content of repeating units derived from comonomers other than TFE and ethylene may be increased up to the upper limit of 50 mol %.

In the fluorinated copolymer (A) to be used for the coating composition in the present invention, when the content of repeating units derived from comonomers other than TFE and ethylene is within such a range, it becomes possible to impart functions such as high solubility, water repellency, oil repellency, curing properties, adhesion to the substrate, etc. without impairing properties of ETFE which is constituted substantially solely by TFE and ethylene.

From the viewpoint of the hardness or the adhesion to the substrate, of the coating film obtainable from the coating composition, the fluorinated copolymer to be used for the coating composition in the present invention preferably has the above crosslinkable groups in the main chain or side chains of its molecule. Such crosslinkable groups may be present at the molecular terminals or in side chains or main chain of the fluorinated copolymer (A). Further, such crosslinkable groups may be used of one type alone or of two or more types in combination in the fluorinated copolymer (A). The type and content of functional groups having adhesive properties to the substrate may suitably be selected depending upon the type and shape of the substrate to be coated with the coating composition, the application, the required adhesive properties, the bonding method, the method for introducing functional groups, etc.

The method for introducing crosslinkable groups to the fluorinated copolymer (A) may, for example, be (i) a method of copolymerizing a copolymerizable monomer having an adhesive functional group with other raw material monomers at the time of polymerization for the fluorinated copolymer (A), (ii) a method of introducing adhesive functional groups to the molecular terminals of the fluorinated copolymer (A) during the polymerization, by a polymerization initiator, a chain transfer agent, etc., or (iii) a method of grafting a compound (graft compound) having an adhesive functional group and a functional group capable of being grafted, to the fluorinated copolymer (A). These introduction methods may be used alone or in combination as the case requires. In a case where the durability is taken into consideration, a fluorinated copolymer (A) produced by at least one of the above methods (i) and (ii) is preferred.

For the coating composition in the present invention, as the above-mentioned fluorinated copolymer (A) having repeating units derived from ethylene and repeating units derived from TFE, it is possible to employ one obtained by copolymerizing ethylene and TFE as essential comonomers for the preparation of the fluorinated copolymer, and further the above-described other comonomers which may be optionally contained, by a usual method, however, it is also possible to employ one available as a commercial product. Such a commercial product of the fluorinated copolymer (A) may specifically be Fluon (registered trademark) ETFE Series, Fluon (registered trademark) LM-ETFE Series, or Fluon (registered trademark) LM-ETFE AH Series, manufactured by Asahi Glass Company, Limited, Neoflon (registered trademark) manufactured by Daikin Industries, Ltd., Dyneon (registered trademark) ETFE manufactured by Dyneon, Tefzel (registered trademark) manufactured by DuPont, or the like.

To the coating composition in the present invention, one of these fluorinated copolymers (A) may be incorporated alone, or two or more of them may be incorporated in combination.

### [Solvent]

The coating composition in the present invention contains a solvent together with the fluorinated copolymer (A). The solvent to be used in the coating composition of the present invention is a solvent capable of dissolving the fluorinated copolymer (A) at a temperature of not higher than the melting point of the fluorinated copolymer (A). Further, it is preferably such a solvent that when the fluorinated copolymer (A) is precipitated from a solution having the fluorinated copolymer (A) dissolved in the solvent, it is capable of maintaining the dispersed state at least at ordinary temperature under ordinary pressure.

As the solvent to be used in the present invention, various solvents may be mentioned within the range satisfying the above conditions. Here, for a solvent to be used to satisfy the above conditions, the polarity of the solvent is preferably within a specific range. In the present invention, the following method is employed wherein a solvent which satisfies the above conditions is selected as a solvent having a polarity within a certain specific range, based on Hansen solubility parameters.

Hansen solubility parameters are ones such that the solubility parameter introduced by Hildebrand is divided into three components of dispersion component δd, polar component δp and hydrogen bonding component δh and represented in a three dimensional space. The dispersion component δd represents the effect by dispersion force, the polar component δp represents the effect by dipolar intermolecular force, and the hydrogen bonding component δh represents the effect by hydrogen bonding force.

The definition and calculation of Hansen solubility parameters are disclosed in “Hansen Solubility Parameter: A Users Handbook (CRC Press, 2007)”, edited by Charles M. Hansen. Further, by using a computer software “Hansen Solubility Parameters in Practice (HSPiP)”, Hansen solubility parameters can be simply estimated. In the present invention, it is preferred to select a solvent to be used by using HSPiP version 3 by employing, with respect to a solvent registered in the database, its values and by employing, with respect to a solvent not registered, its estimated values.

Usually, Hansen solubility parameters for a certain polymer can be determined by a test wherein samples of such a polymer are dissolved in many different solvents, of which Hansen solubility parameters have already been known, and the solubilities are measured. Specifically, such a sphere (solubility sphere) is to be found out whereby all three dimensional points of the solvents which dissolved the polymer among the solvents used for the above solubility test are included inside of the sphere, and points of the solvents which did not dissolve the polymer are located outside the sphere, and the central coordinate of such a sphere is taken as Hansen solubility parameters of the polymer.

Here, in a case where Hansen solubility parameters of another solvent not used for the measurement of Hansen solubility parameters of the above polymer are (δd, δp, δh), if the point represented by such coordinates is included inside of the solubility sphere of the above polymer, such a solvent is considered to dissolve the above polymer. On the other hand, if such a coordinate point is located outside of the solubility sphere of the above polymer, such a solvent is considered not to be able to dissolve the above polymer.

In the present invention, by utilizing the above Hansen solubility parameters, it is possible to use, as preferred solvents, a group of solvents which are solvents capable of dissolving the fluorinated copolymer (A) contained in the coating composition, at a temperature of not higher than its melting point and which are in a certain distance from coordinates (15.7, 5.7, 4.3) being Hansen solubility parameters of diisopropyl ketone as the most suitable standard solvent to disperse the fluorinated copolymer (A) in the form of microparticles at room temperature.

That is, the value R based on Hansen solubility parameters and represented by the following formula (1) is used as the dissolution index for the fluorinated copolymer (A).

R=4×(δd−15.7)²+(δp−5.7)²+(δh−4.3)² (1)

wherein δd, δp and δh represent the dispersion component, the polar component and the hydrogen bonding component, respectively, in Hansen solubility parameters, and their units are (MPa)^{1/2}, respectively.

Of the solvent in the present invention, the dissolution index (R) calculated by the above formula (1) by using Hansen solubility parameter coordinates (δd, δp, δh) of the solvent, is preferably less than 25, more preferably less than 16. A solvent having

Hansen solubility parameters whereby R represented by the above formula (1) falls within this range, has high affinity to the fluorinated copolymer (A) and presents high solubility and dispersibility when the fluorinated copolymer (A) is in the form of microparticles.

Further, the solvent to be used in the present invention may be a solvent composed of one compound or a solvent mixture composed of two or more compounds, and the value R calculated by the above formula (1) based on Hansen solubility parameters can be used as the dissolution index for the fluorinated copolymer (A). For example, in a case where a solvent mixture is used, average Hansen solubility parameters are obtained by a mixing ratio (volume ratio) of solvents to be used, and the above dissolution index (R) can be calculated by using them as Hansen solubility parameters.

Further, in the present invention, the boiling point of the solvent is preferably at most 210° C., more preferably at most 180° C., from the viewpoint of the handling efficiency and removability of the solvent after the application. On the other hand, if the boiling point of the solvent is too low, there is, for example, a problem such that bubbles are likely to be formed at the time of removal by evaporation (hereinafter referred to also as drying) of the solvent after coating the composition, and therefore, it is preferably at least 40° C., more preferably at least 55° C., particularly preferably at least 80° C.

As the solvent which satisfies the above conditions, preferred may, for example, be a C₃₋₁₀ ketone, ester, carbonate or ether, and more preferred may, for example, be a C₅₋₉ ketone or ester. Specific examples include, for example, methyl ethyl ketone, 2-pentanone, methyl isopropyl ketone, 2-hexanone, methyl isobutyl ketone, pinacoline, 2-heptanone, 4-heptanone, diisopropyl ketone, isoamyl methyl ketone, 2-octanone, 2-nonanone, diisobutyl ketone, ethyl formate, propyl formate, isopropyl formate, butyl formate, isobutyl formate, sec-butyl formate, t-butyl formate, amyl formate, isoamyl formate, hexyl formate, cyclohexyl formate, heptyl formate, octyl formate, 2-ethylhexyl formate, methyl acetate, ethyl acetate, propyl acetate, isopropyl acetate, butyl acetate, acetate, sec-butyl acetate, t-butyl acetate, amyl acetate, isoamyl acetate, hexyl acetate, cyclohexyl acetate, heptyl acetate, octyl acetate, 2-ethylhexyl acetate, methyl propionate, ethyl propionate, propyl propionate, isopropyl propionate, butyl propionate, isobutyl propionate, sec-butyl propionate, t-butyl propionate, amyl propionate, isoamyl propionate, hexyl propionate, cyclohexyl propionate, heptyl propionate, methyl butyrate, ethyl butyrate, propyl butyrate, isopropyl butyrate, butyl butyrate, isobutyl butyrate, sec-butyl butyrate, t-butyl butyrate, amyl butyrate, isoamyl butyrate, hexyl butyrate, cyclohexyl butyrate, methyl isobutyrate, ethyl isobutyrate, propyl isobutyrate, isopropyl isobutyrate, butyl isobutyrate, isobutyl isobutyrate, sec-butyl isobutyrate, t-butyl isobutyrate, amyl isobutyrate, isoamyl isobutyrate, hexyl isobutyrate, cyclohexyl isobutyrate, methyl valerate, ethyl valerate, propyl valerate, isopropyl valerate, butyl valerate, isobutyl valerate, sec-butyl valerate, t-butyl valerate, amyl valerate, methyl isovalerate, ethyl isovalerate, propyl isovalerate, isopropyl isovalerate, butyl isovalerate, isobutyl isovalerate, sec-butyl isovalerate, t-butyl isovalerate, amyl isovalerate, methyl hexanoate, ethyl hexanoate, propyl hexanoate, isopropyl hexanoate, butyl hexanoate, isobutyl hexanoate, sec-butyl hexanoate, t-butyl hexanoate, methyl heptanoate, ethyl heptanoate, propyl heptanoate, isopropyl heptanoate, methyl octanoate, ethyl octanoate, methyl nonanate, methyl cyclohexane carboxylate, ethyl cyclohexane carboxylate, propyl cyclohexane carboxylate, isopropyl cyclohexane carboxylate, 2-propoxyethyl acetate, 2-butoxyethyl acetate, 2-pentyloxyethyl acetate, 2-hexyloxyethyl acetate, 1-ethoxy-2-acetoxypropane, 1-propoxy-2-acetoxypropane, 1-butoxy-2-acetoxypropane, 1-pentyloxy-2-acetoxypropane, 3-methoxybutyl acetate, 3-ethoxybutyl acetate, 3-propoxybutyl acetate, 3-butoxybutyl acetate, 3-methoxy-3-methylbutyl acetate, 3-ethoxy-3-methylbutyl acetate, 3-propoxy-3-methylbutyl acetate, 4-methoxybutyl acetate, 4-ethoxybutyl acetate, 4-propoxybutyl acetate, 4-butoxybutyl acetate, tetrahydrofuran. Here, each of these solvents is a solvent wherein R calculated from the above formula (1) is less than 25.

Among them, the following compounds may be exemplified specifically as more preferred compounds as the solvent of the present invention.

Methyl ethyl ketone, 2-pentanone, methyl isopropyl ketone, 2-hexanone, methyl isobutyl ketone, pinacoline, 2-heptanone, 4-heptanone, diisopropyl ketone, isoamyl methyl ketone, 2-octanone, 2-nonanone, diisobutyl ketone, isopropyl formate, isobutyl formate, sec-butyl formate, t-butyl formate, amyl formate, isoamyl formate, hexyl formate, heptyl formate, octyl formate, 2-ethylhexyl formate, ethyl acetate, propyl acetate, butyl acetate, isobutyl acetate, t-butyl acetate, amyl acetate, isoamyl acetate, hexyl acetate, cyclohexyl acetate, heptyl acetate, methyl propionate, ethyl propionate, propyl propionate, isopropyl propionate, butyl propionate, isobutyl propionate, sec-butyl propionate, t-butyl propionate, amyl propionate, isoamyl propionate, hexyl propionate, cyclohexyl propionate, methyl butyrate, ethyl butyrate, propyl butyrate, isopropyl butyrate, butyl butyrate, isobutyl butyrate, sec-butyl butyrate, t-butyl butyrate, amyl butyrate, isoamyl butyrate, methyl isobutyrate, ethyl isobutyrate, propyl isobutyrate, isopropyl isobutyrate, butyl isobutyrate, isobutyl isobutyrate, sec-butyl isobutyrate, t-butyl isobutyrate, amyl isobutyrate, isoamyl isobutyrate, methyl valerate, ethyl valerate, propyl valerate, isopropyl valerate, butyl valerate, isobutyl valerate, sec-butyl valerate, t-butyl valerate, methyl isovalerate, ethyl isovalerate, propyl isovalerate, isopropyl isovalerate, butyl isovalerate, isobutyl isovalerate, sec-butyl isovalerate, t-butyl isovalerate, methyl hexanoate, ethyl hexanoate, propyl hexanoate, isopropyl hexanoate, methyl heptanoate, ethyl heptanoate, methyl octanoate, methyl cyclohexanecarboxylate, ethyl cyclohexanecarboxylate, propyl cyclohexanecarboxylate, isopropyl cyclohexanecarboxylate, 2-propoxyethyl acetate, 2-butoxyethyl acetate, 2-pentyloxyethyl acetate, 1-ethoxy-2-acetoxypropane, 1-propoxy-2-acetoxypropane, 1-butoxy-2-acetoxypropane, 3-ethoxybutyl acetate, 3-propoxybutyl acetate, 3-methoxy-3-methylbutyl acetate, 3-ethoxy-3-methylbutyl acetate, 4-methoxybutyl acetate, 4-ethoxybutyl acetate and 4-propoxybutyl acetate.

Here, each of these solvents is a solvent wherein R calculated from the above formula (1) is less than 16.

The above solvents may be used alone or in combination as a mixture of two or more of them in a range where the above conditions of the present invention are satisfied. Further, so long as the above conditions are satisfied, a solvent other than those mentioned above may be used as mixed to the above solvent. Furthermore, so long as the solvent mixture satisfies the above conditions, two or more solvents other than those mentioned above may be used as mixed.

In such a solvent mixture, the blend amounts are suitably adjusted so that the dissolution index (R) calculated from Hansen solubility parameters of the respective solvents constituting the solvent mixture and their volume ratio, is preferably less than 25, more preferably less than 16.

### [Coating Composition]

The fluorinated copolymer (A) contained in the coating composition in the present invention may be present in a dissolved state but is preferably present in a state dispersed in a solvent, as described below. Here, in a case where the fluorinated copolymer (A) is present in a dispersed state, the fluorinated copolymer (A) is preferably a fluorinated copolymer (A) precipitated from a solution having it dissolved in a solvent as described below. By precipitating the fluorinated copolymer (A) from a solution having it dissolved in a solvent, the fluorinated copolymer (A) will be dispersed in the solvent in the form of microparticles. In such a case, the average particle size of microparticles of the fluorinated copolymer (A) is preferably within a range of from 0.005 to 2 μm, more preferably from 0.005 to 1 μm, as an average particle size measured by a small-angle X-ray scattering technique at 20° C. When the average particle size of microparticles of the fluorinated copolymer (A) is within this range in the coating composition in the present invention, it is possible to form a coating film which is uniform and excellent in transparency, planarity and adhesive properties.

The content of the fluorinated copolymer (A) in the coating composition in the present invention may suitably be changed depending upon the film thickness of the desired molded product. From the viewpoint of the film forming properties, the content of the fluorinated copolymer (A) is preferably from 0.05 to 30 mass %, more preferably from 0.1 to 20 mass %, based on the total amount of the composition. When the content is within this range, the handling efficiency such as the viscosity, drying speed or uniformity of the film will be excellent, and it will be possible to form a uniform coating film made of the fluorinated copolymer (A).

The content of the solvent in the coating composition in the present invention is preferably from 70 to 99.95 mass %, more preferably from 80 to 99.9 mass %, based on the total amount of the composition, from the viewpoint of the moldability at the time of obtaining a molded product by using the composition. When the content of the solvent is within this range, the coating composition will be excellent in handling efficiency at the time of its application in the preparation of a coating film, and the obtainable coating film containing the fluorinated copolymer (A) can be made homogeneous and uniform.

### [Process for Producing Coating Composition]

The process for producing a coating composition of the present invention will now be described. Specifically, the process of the present invention is used as a process for producing the above-described coating composition of the present invention.

The process for producing a coating composition of the present invention preferably comprises the following steps (1) and (2).

(1) A step of dissolving a fluorinated copolymer (A) having repeating units derived from ethylene and repeating units derived from tetrafluoroethylene, in a solvent capable of dissolving the fluorinated copolymer (A) at a temperature of not higher than the melting point of the fluorinated copolymer (A) (hereinafter referred to as “the dissolving step”).

(2) A step of precipitating the fluorinated copolymer (A) in the form of microparticles in the solvent in the solution, to convert the solution to a dispersion having the microparticles dispersed in the solvent (hereinafter referred to as “the precipitation step”).

### (1) Dissolving Step

The solvent to be used in the dissolving step is a solvent satisfying the above conditions i.e. a solvent which is capable of dissolving the fluorinated copolymer (A) at a temperature of not higher than the melting point of the fluorinated copolymer (A). Further, in a case where the precipitation step is carried out to precipitate microparticles of the fluorinated copolymer (A) from a solution having the fluorinated copolymer dissolved in the solvent, the solvent to be used is preferably capable of dispersing the fluorinated copolymer stably in the form of microparticles at least at ordinary temperature under ordinary pressure.

The conditions such as the temperature, pressure, stirring, etc. in the dissolving step are not particularly limited so long as they are conditions under which the fluorinated copolymer (A) can be dissolved in the above solvent, but as the temperature condition in the dissolving step, a temperature lower than the melting point of the fluorinated copolymer (A) to be used is preferred. The melting point of the fluorinated copolymer (A) to be used in the present invention is about 275° C. even at the highest, and therefore, the temperature in the step of dissolving it in the above solvent is preferably about a temperature of not higher than 275° C. The temperature for dissolving the fluorinated copolymer (A) in the solvent is more preferably not higher than 230° C., particularly preferably not higher than 200° C. Further, the lower limit of the temperature in this dissolving step is preferably 0° C., more preferably 20° C. If the temperature in the dissolving step is lower than 0° C., a sufficient dissolved state may not be obtained, and if it exceeds 275° C., a practical operation may not be easily carried out.

In the dissolving step in the process for producing the coating composition of the present invention, conditions other than the temperature are not particularly limited, and the dissolving operation is usually preferably carried out under a condition from ordinary pressure to a slightly elevated pressure at a level of 0.5 MPa. In a case where the boiling point of the solvent is lower than the temperature in the dissolving step depending upon the type of the fluorinated copolymer (A) or the solvent, a method may be mentioned for dissolution in a pressure resistant container under at least not higher than a naturally-occurring pressure, preferably not higher than 3 MPa, more preferably not higher than 2 MPa, further preferably not higher than 1 MPa, most preferably under a condition of not higher than ordinary pressure. However, usually, the dissolution can be carried out under a condition from about 0.01 to 1 MPa.

The dissolution time depends on e.g. the content of the fluorinated copolymer (A) in the coating composition of the present invention or the shape of the fluorinated copolymer (A). The shape of the fluorinated copolymer (A) to be employed is preferably a powder form from the viewpoint of the operation efficiency to shorten the dissolution time, but in view of availability, etc., one having another shape such as a pellet form may also be used.

A dissolving means in the dissolving step is not particularly limited, and a common method may be employed. For example, necessary amounts of the respective components to be incorporated to the coating composition are weighed, and these components may be uniformly mixed and dissolved in the solvent preferably at a temperature of at least 0° C. and at most the melting point of the fluorinated copolymer to be used, more preferably from 0 to 230° C., particularly preferably from 20 to 200° C. Here, it is preferred to carry out a dissolution by means of a common stirring and mixing machine such as a homomixer, a Henschel mixer, a Banbury mixer, a pressure kneader or a single screw or twin screw extruder, from the viewpoint of the efficiency. Further, in a case where heating is necessary in the dissolving step, mixing and heating of the various raw material components may be carried out simultaneously, or a method may be employed wherein the respective raw material components are mixed, and then heated with stirring as the case requires.

In a case where the dissolution is carried out under an elevated pressure, an apparatus such as an autoclave equipped with a stirrer may be employed. The shape of stirring vanes may, for example, be a marine propeller vane, an anchor vane, a turbine vane or the like. In a case where the operation is carried out in a small scale, a magnetic stirrer or the like may be employed.

As the coating composition in the present invention, it is also possible to use a composition containing the fluorinated copolymer (A) in such a state that it is dissolved by the dissolving step without carrying out the precipitation step.

### (2) Precipitation Step

The solution having the fluorinated copolymer (A) dissolved in the above solvent, as obtained in the above dissolving step (1), is held under such a condition that the fluorinated copolymer (A) will be precipitated in the above solvent, usually at ordinary temperature under ordinary pressure, whereby the fluorinated copolymer (A) will be precipitated in the solvent. Specifically, in a case where the above dissolving step (1) is carried out under heating, the obtained solution is cooled to a temperature of not higher than the temperature at which the fluorinated copolymer (A) is precipitated, usually to ordinary temperature, whereby it is possible to precipitate microparticles of the fluorinated copolymer (A) in the above solvent. In such a case, the cooling method is not particularly limited, and it may be annealing or quenching.

In the precipitation step, the fluorinated copolymer (A) is usually precipitated in the form of microparticles, whereby a composition having the microparticles dispersed in the solvent can be obtained. Here, the average particle size of microparticles of the fluorinated copolymer (A) to be precipitated in this precipitation step is preferably within a range of from 0.005 to 2 μm, more preferably from 0.005 to 1 μm, as an average particle size measured by a small-angle X-ray scattering technique at 20° C.

In the present invention, as the coating composition, it is preferred to use a composition containing the fluorinated copolymer (A) in such a state as dispersed in the form of microparticles.

### [Other Optional Components]

The coating composition in the present invention may contain other optional components, as the case requires, within a range not to impair the effects of the present invention. Such optional components may, for example, be various additives including, for example, a curing agent, a curing accelerator, an adhesion-improving agent, a surface-adjusting agent, an antioxidant, a photostabilizer, an ultraviolet absorber, a crosslinking agent, a lubricant, a plasticizer, a thickening agent, a delustering agent, a dispersion stabilizer, a bulking agent (filler), a reinforcing agent, a leveling agent, a pigment, a dye, a flame retardant, an antistatic agent, other resins, etc. The content of such optional components not to impair the effects of the present invention may, for example, be a content of not higher than 30 mass % based on the total amount of the coating composition.

As the process includes a step of dissolving the fluorinated copolymer (A) in a solvent to form a solution, the coating composition in the present invention may contain the above additives in a large amount as the case requires, and such additives may be uniformly mixed. Further, by using such a coating composition containing the above additives at a high concentration, it becomes possible to provide necessary functions with a thinner film thickness, whereby it becomes possible to reduce the amount of the fluorinated copolymer (A) to be used.

It is preferred to add a curing agent in order to cure the coating material; however, the coating material may be cured only by drying depending on the type of the crosslinkable groups, and accordingly, a curing agent is not required to be added in such a case. The curing agent may be properly selected depending on the crosslinkable groups contained in fluorinated copolymer (A).

For example, in the case where the crosslinkable group is a hydroxy group, an isocyanate curing agent, a melamine resin, a silicate compound, an isocyanate-containing silane compound or the like is selected; in the case of a carboxy group, an amino curing agent or an epoxy curing agent is selected; in the case of an amino group, a carbonyl-containing curing agent, an epoxy curing agent or an acid anhydride curing agent is selected; in the case of an epoxy group, a carboxy group is selected; and in the case of an isocyanate group, a hydroxy group is selected. The crosslinkable group requiring no curing agent may, for example, be a hydrolyzable silyl group.

Particularly in the case where the fluorinated copolymer has hydroxy groups, the curing agent is preferably a polyisocyanate, more preferably, among polyisocyanates, a non-yellowing polyisocyanate or a modified body of a non-yellowing polyisocyanate.

The non-yellowing modified polyisocyanate is preferably IPDI (isophorone diisocyanate), HMDI (hexamethylene diisocyanate), HDI (hexane diisocyanate) or a modified body thereof.

The modified body is preferably, for example, a polyisocyanate having the isocyanate group blocked using ε-caprolactam (E-CAP), methyl ethyl ketone oxime (MEK-OX), methylisobutyl ketone oxime (MIBK-OX), pyraridine or triazine (TA), or polyisocyanates having the polyisocyanate groups coupled to form a urethodion bond.

As the curing promoter, for example, a tin-, another metallic-, organic acid-, or amine-curing promoter may be used.

The adhesion improver is not particularly limited, but, for example, a silane coupling agent may be preferably used. The silane coupling agent is preferably, for example, an aminoalkylsilane such as 3-aminopropyltriethoxysilane, 3-aminopropyltrimethoxysilane, N-2-(aminoethyl)-3-aminopropyltrimethoxysilane or ureidopropyltriethoxysilane; an unsaturated alkylsilane such as vinyltriethoxysilane, vinyltrimethoxysilane, 3-(trimethoxysilyl)propyl (meth)acrylate or 3-(triethoxysilyl)propyl (meth)acrylate; an epoxysilane such as 2-(3,4-epoxycyclohexyl)ethyltrimethoxysilane or 3-glycidoxypropyltrimethoxysilane; or 3-mercaptopropyltrimethoxysilane, 3-isocyanatepropyltriethoxysilane, methyltriethoxysilane, methyltrimethoxysilane or the like.

The pigment has effects of improving esthetic appearance of the back sheet, increasing light use efficiency by reflecting light, and so on. As the pigment, for example, a white pigment such as titanium oxide or calcium carbonate, a black pigment such as carbon black, or another pigment such as a composite metal is added.

Among such pigments, titanium oxide as a white pigment is known to decompose and deteriorate the coating film layer containing the pigment by the photocatalytic action. Accordingly, it is preferred to use titanium oxide made into composite particles which comprise, sequentially from the center, particles containing titanium oxide, a first covering layer covering the above particles and containing cerium oxide, and a second covering layer covering the first coating film layer and containing silicon oxide.

The composite particles may have another covering layer inside or outside of the cerium oxide covering layer or the silicon oxide covering layer. For example, it is preferred that the composite particles have a covering layer of silicon oxide between the particles containing titanium oxide and the first covering layer covering the particles and containing cerium oxide.

Further, to the outermost covering layer of the composite particles, depending on required properties for the composite particles, a metal compound other than the metal compound constituting the covering layer is preferably added. For example, it is preferred that zirconia is added in order to harden the covering layer to keep the pigment from collapsing, or alumina is added in order to increase the hydrophilic property to improve the aqueous dispersibility. In the case where the outermost layer of the above composite particles is the above second layer containing silicon oxide, it is preferred that the above zirconia or alumina is added to silicon oxide. When a metal compound other than the metal compound constituting the covering layer is added to the covering layer, the amount of the metal compound to be added is preferably from 10 to 50 mass %, more preferably from 20 to 30 mass %, in the total mass of the metal compounds constituting the covering layer.

The leveling agent is preferably, for example, a polyether-modified polydimethylsiloxane or a polyether-modified siloxane.

Since solar cells are used outdoor for a long period of time, where ultraviolet rays are strong, the countermeasure against the deterioration of the back sheet by ultraviolet rays is important. Accordingly, it is preferred that an ultraviolet absorbing agent is added to the coating material containing the fluorinated copolymer (A) as an essential component to impart a function to absorb ultraviolet rays, to the coating film.

As the ultraviolet absorbing agent, an organic ultraviolet absorbing agent or an inorganic ultraviolet absorbing agent may be used. Such an organic compound may, for example, be an ultraviolet absorbing agent of a salicylic acid ester type, a benzotriazole type, a benzophenone type, or a cyanoacrylate type; and such an inorganic compound is preferably a filler-type inorganic ultraviolet absorbing agent such as titanium oxide, zinc oxide or cerium oxide.

When titanium oxide is used as the ultraviolet absorbing agent, it is preferred to use the above titanium oxide made into composite particles.

Such ultraviolet absorbing agents may be used alone, or in combination as a mixture of two or more of them. The amount of the ultraviolet absorbing agent is preferably from 0.1 to 15 mass % in the total mass of the solid content of the fluorinated copolymer (A) in the coating material. If the amount of the ultraviolet absorbing agent is too small, the effect of improving the light resistance cannot be sufficiently obtained, and if it is too large, the effect will be saturated.

The photostabilizer may, for example, be a hindered amine photostabilizer, and is preferably, for example, ADK STB LA-62, ADK STB LA-67 (tradenames, manufactured by ADEKA ARGUS CHEMICAL Co., Ltd.), TINUVIN 292, TINUVIN 144, TINUVIN 123 or TINUVIN 440 (tradenames, manufactured by Ciba Specialty Chemicals).

Such photostabilizers may be used alone or in combination as a mixture of two or more of them. The photostabilizer may be used in combination with the ultraviolet absorbing agent.

The thickening agent may, for example, be a polyurethane associative thickening agent.

As the delustering agent, a common inorganic or organic delustering agent such as an ultrafine powdered synthetic silica may be used.

Said other resins may, for example, be non-fluorinated resins such as an acrylic resin, a polyester resin, an acrylpolyol resin, a polyester polyol resin, a urethane resin, an acrylsilicone resin, a silicone resin, an alkyd resin, an epoxy resin, an oxetane resin, an amino resin, etc. Other resins may be resins which have crosslinkable groups and which may be crosslinked and cured by a curing agent. In a case where other resins are to be incorporated to the coating composition of the present invention, the content of such other resins is preferably from 1 to 200 parts by mass per 100 parts by mass of the fluorinated copolymer (A).

The concentration of the fluorinated copolymer (A) in the coating composition prepared as described above, is preferably from 1 to 50 mass % based on the total mass of the coating material.

### [Substrate Sheet]

Material for the substrate sheet is not particularly limited, and a polyolefin such as polyethylene or polypropylene; a polyvinyl halide such as polyvinyl chloride, polyvinylidene chloride, polyvinyl fluoride or polyvinylidene fluoride; a polyester such as PET or polybutylene terephthalate; a polyamide such as Nylon 6, Nylon 66 or MXD nylon (methaxylenediamine/adipic acid copolymer); a polymer of an olefin having a substituent such as polyvinyl acetate, polyvinyl alcohol or polymethyl methacrylate; or a copolymer such as EVA or an ethylene/vinyl alcohol copolymer, may be used.

Among them, PET, EVA, polyvinyl alcohol, polyvinylidene chloride, Nylon 6, Nylon 66 or an ethylene/vinyl alcohol copolymer is preferred.

The back sheet of the present invention has a coating film and a substrate sheet, whereby it has water/moisture-proof property. However, a higher water/moisture-proof property is required under a certain condition in use of a solar cell. In such a case, a layer made of a metal or a metal compound (hereinafter, a metal and a metal compound will be collectively referred to as “a metal”, and the layer made of a metal or a metal compound will be collectively referred to as “a metal layer”) is preferably provided on one or each side of the substrate sheet to obtain a water-impermeable sheet.

The metal layer may be provided by vapor-depositing a metal or a metal compound on the surface of the substrate sheet or adhering a foil of a metal or a metal compound with an adhesive to the surface of the substrate sheet. The foil and the substrate sheet are preferably adhered via an adhesive layer made of an adhesive.

The metal is preferably one excellent in water/moisture-proof property and having high corrosion resistance. Further, in the case where a metal layer is provided by vapor-deposition, a metal may be selected from metals which can be vapor-deposited.

The metal may, for example, be a metal selected from the group consisting of silicon, magnesium, zirconium, zinc, tin, nickel, titanium and aluminum, or a compound of such a metal or stainless steel. Among them, the metal used for vapor-deposition is preferably silicon, aluminum, aluminum oxide, silicon oxide, silicon nitride-oxide or silicon nitride. In the vapor-deposition, one type of such a metal may be used, or two or more types of such metals may be used in combination.

On the other hand, the metal in the case where a foil of a metal is adhered with an adhesive is preferably aluminum, titanium or stainless steel.

### [Construction of Back Sheet]

The back sheet of the present invention comprises the above substrate sheet and a coating film formed from a coating composition containing the above fluorinated copolymer (A) as an essential component formed on one side or each side of the substrate sheet. Hereinafter, the surface of the substrate sheet on the solar cell side will be referred to as an inner surface, and the surface on the side opposite to the solar cell will be referred to as an outer surface.

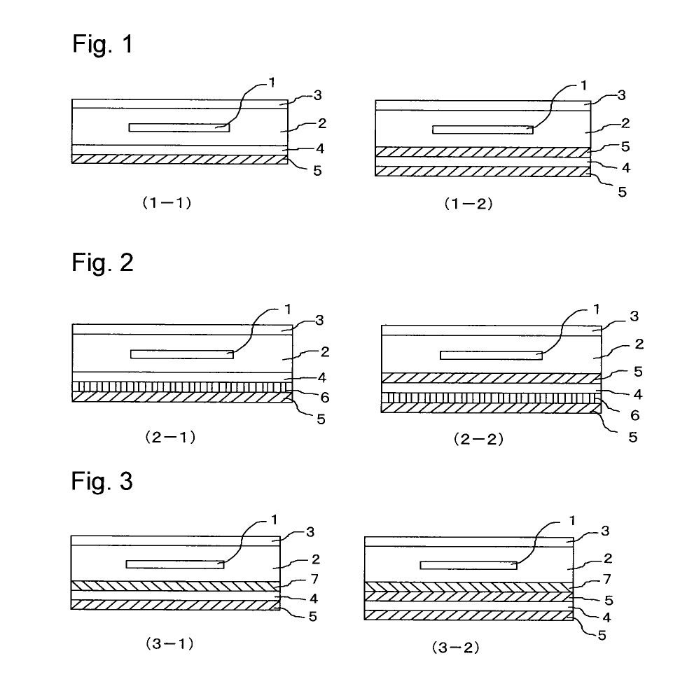

FIG. 1 shows embodiments wherein a coating film 5 is formed on one side of a substrate sheet 4, and FIG. (1-1) is for the case where the coating film 5 is formed on the outer surface, and FIG. (1-2) is for the case where the coating film 5 is formed on each side of the substrate sheet 4.

The coating film 5 is preferably formed only on the outer surface of the substrate sheet 4 or on the surface of the substrate sheet, from the viewpoint of weatherability. Further, from the viewpoint of economic efficiency and weight reduction, the coating film is preferably formed only on the outer surface of the substrate sheet. That is, the preferred constitution of the back sheet is the constitution of FIG. (1-1), which has a substrate sheet and a coating film laminated on the outer surface of the substrate sheet.

In the case where the substrate sheet has a metal layer 6, the metal layer is provided on one or each surface of the substrate sheet 4, but it is usually provided only on one surface from an economic viewpoint. In order to efficiently prevent the substrate sheet 4 from deterioration due to water, the embodiment of FIG. (2-1) or FIG. (2-2) in FIG. 2 is preferred, wherein a metal layer 6 is provided on the outer surface of the substrate sheet having a possibility of intrusion of water. Further, the preferred construction of the back sheet in the case of having a metal layer 6 is the construction of FIG. (2-1) which comprises a substrate sheet 4, a metal layer 6 laminated on the outer surface of the substrate sheet and a coating film 5 laminated on the outer surface of the metal layer.

Further, when a coating film is formed on the surface of the substrate sheet which may have a metal layer, the coating film may be directly formed, or the coating film may be formed after a primer layer is formed. In the case where the coating film is directly formed, it is preferably by means of directly applying the coating composition containing the fluorinated copolymer (A) as an essential component. In the case where a primer layer is formed, it is preferred that a coating material for primer is applied to the surface of the substrate sheet which may have a metal layer, and then a coating composition containing the fluorinated copolymer (A) as an essential component is applied. The primer coating material may, for example, be an epoxy resin, a urethane resin, an acrylic resin, a silicone resin or a polyester resin.

Further, the back sheet of the present invention may have a layer of another polymer (hereinafter also referred to as polymer (B)) laminated on the outermost surface which contacts with a sealing material layer at the inner surface side. Such another polymer layer is preferably a layer comprising a polymer other than the above coating film, and for example, the polymer provided as an example of the above material for the substrate sheet may be adopted. The polymer layer is preferably an EVA layer which can improve the adhesion to a resin (hereinafter referred to as a sealing resin) which seals a solar cell.

The polymer layer may be directly provided on the substrate sheet of the back sheet, or may be provided on another layer via such another layer such as a coating film between the polymer layer and the substrate sheet.

FIG. 3 shows embodiments of the back sheet of the present invention, each of which has an EVA layer on the surface contacting with a sealing material layer at the inner surface side, and the embodiments of FIG. (3-1) and FIG. (3-2) are such that an EVA layer is formed on the surface contacting with the sealing material layer at the inner surface side in the embodiments of the back sheet of FIG. (1-1) and FIG. (1-2), respectively. In such embodiments, a metal layer may be provided on one side or each side of the substrate sheet, and it is particularly preferred that a metal layer is provided only on the outer surface of the substrate sheet.

Further, when the adhesion between respective layers forming the back sheet is low, a layer (hereinafter referred to as an adhesive layer) of another compound having adhesion may be provided.

For example, an adhesive layer is provided between the substrate sheet and a metal foil in the case where a metal layer comprising a metal foil is formed on the surface of the substrate sheet. Further, in order to improve adhesion of another polymer (B) layer, an adhesive layer may be provided on one surface or each surface of such another polymer (B) layer, preferably on one side of such another polymer (B) layer. In the case where such another polymer (B) layer is made of EVA, it is preferred that an adhesive layer is provided on the surface of the EVA layer at the side opposite to the surface contacting with the sealing material layer. In the case where such another polymer layer is made of EVA and the sealing material layer is made of EVA, both layers may be adhered to each other by compression. The adhesive may be properly changed according to the materials of the layers to be laminated, but it may, for example, be a polyester adhesive, an acrylic adhesive, a urethane adhesive, an epoxy adhesive, a polyamide adhesive or a polyimide adhesive.

Further, in the back sheet of the present invention, another layer may be formed between respective layers described as above, on the surface contacting with the sealing material and on the outermost surface, as necessary.

The back sheet of the present invention preferably has a high electrical insulation. In order to have a high electrical insulation, each layer constituting the back sheet is preferably composed of a material having a low permittivity. For example, an adhesive having a low permittivity is preferably used for the adhesive layer, and an epoxy adhesive, a polyamide adhesive or a polyimide adhesive is more preferred from the viewpoint of low permittivity. The permittivity is preferably at most 3.5, more preferably at most 3.3, most preferably at most 3.0, although it depends on the properties required for a solar cell module. The permittivity in the present invention is a value measured by the method in accordance with JIS C-2151, and is a value measured at 1 kHz at 23° C.

The thickness of each layer constituting the back sheet may be changed depending on the required properties. For example, the thickness of the coating film of a coating material containing a fluorinated copolymer (A) as an essential component is preferably from 5 to 75 μm. The thickness of the metal layer is preferably 0.01 to 50 μm. The thickness of the substrate sheet is preferably 25 to 200 μm. The thickness of another polymer (B) layer is preferably from 50 to 200 μm. The thickness of the adhesive layer is from 0.1 to 25 μm. Further, the total film thickness of the back sheet of the present invention is preferably from 30 to 300 μm.

### [Solar Cell]

The back sheet of the present invention constitutes a solar cell module in combination with a solar cell. Usually, a surface sheet, a sealing layer wherein a solar cell is sealed with a resin and a back sheet are laminated in this order to constitute a solar cell module. Further, when the adhesion by the lamination is insufficient, an adhesive layer may be provided.

As the surface sheet, a glass substrate is usually used, but a flexible material such as a resin sheet may also be used. The back sheet of the present invention has a thin film thickness and enables reduction in weight, and therefore it may be suitably used for a flexible solar cell.

### EXAMPLES

Now, the present invention will be described in detail with reference to Examples. It should be understood, however, that the present invention is by no means limited to these Examples.

### [Preparation of Coating Composition (A1) of ETFE1]

### <Coating Composition (A1)>

In a pressure resistant reactor made of borosilicate glass, 2.40 g of ETFE1 (constituting monomers and molar ratio: tetrafluoroethylene/ethylene/hexafluoropropylene/3,3,4,4,5,5,6,6,6-nonafluoro-1-hexene/itaconic anhydride=44.6/45.6/8.1/1.3/0.4, melting point: 192° C., hereinafter referred to as “ETFE1”) as the fluorinated copolymer (A) and 37.60 g of diisopropyl ketone (R calculated by the above formula (1) (hereinafter referred to simply as “R”)=0) were put and heated to 140° C. with stirring, thereby to form a uniform transparent solution.

The reactor was gradually cooled to room temperature, to obtain a uniform dispersion of microparticles of ETFE1 free from sedimentation (concentration of ETFE1: 6 wt %). The average particle size of microparticles of ETFE1 was 20 nm as an average particle size measured by a small-angle X-ray scattering technique at 20° C. Further. This dispersion was diluted to 0.05 wt % and observed by a transmission electron microscope, whereby the primary particle size was confirmed to be from 20 to 30 nm.

This dispersion was applied on a glass substrate at room temperature by potting, followed by air drying and then heated on a hot plate of 120° C. for 5 minutes to obtain a glass substrate having a thin film of ETFE1 formed on its surface. The obtained thin film was observed by an optical microscope (50 magnifications), whereby it was confirmed to be a uniform smooth film. Further, the film thickness was measured by a stylus profilometer and found to be 3 μm. The adhesion of the obtained ETFE1 film was evaluated, whereby no peeling was observed.

### <Coating Composition (A2)>

A coating composition (A2) was obtained in the same manner as for the coating composition (A1) except that cyclohexanone (R=25.6) was used as the solvent.

### <Coating Composition (A3)>

A coating composition (A3) was obtained in the same manner as for the coating composition (A1) except that 1.20 g of ETFE2 (constituting monomers and molar ratio: tetrafluoroethylene/ethylene/hexafluoropropylene/3,3,4,4,5,5,6,6,6-nonafluoro-1-hexene/itaconic anhydride=47.7/42.5/8.4/1.2/0.2, melting point: 188° C., hereinafter referred to as “ETFE2”) as the fluorinated copolymer (A) and 38.80 g of 2-hexanone (R=0.8) as the solvent, were used.

### [Preparation of Composite Particles]

### <Preparation of Composite Particles (C)>

500 g of titanium oxide pigment (CR50, manufactured by Ishihara Sangyo Kaisha, Ltd., average particle size: 0.20 μm) was added to 10 L of pure water and dispersed using DESPA MILL (manufactured by Hosokawa Micron Corporation) for 1 hour to obtain an aqueous dispersion. While the aqueous dispersion was heated to 80° C. and stirred, 264 g of a cerium nitrate aqueous solution (cerium content: 10 mass % as calculated as CeO₂) was dropped into the aqueous dispersion. A sodium hydroxide solution was added to the aqueous dispersion, and the dispersion was neutralized to pH 7 to 9 to deposit cerium hydroxide on the surface of the titanium oxide pigment. The dispersion containing the particles covered with cerium hydroxide was filtrated, and the particles covered with cerium hydroxide were washed with water and dried. A mass of the particles covered with cerium hydroxide was crushed to obtain particles covered with cerium hydroxide.

The particles covered with cerium hydroxide were added to 10 L of pure water, and dispersed using DESPA MILL for 1 hour to obtain an aqueous dispersion. While the aqueous dispersion was heated to 80° C. and stirred, 348 g of sodium silicate No. 3 (silicon content: 28.5 mass % as calculated as SiO₂) was added to the aqueous dispersion. At that time, diluted sulfuric acid was also added to maintain pH of the dispersion at 9 to 11, followed by stirring for 1 hour, and then sulfuric acid was added to adjust pH of the dispersion to be 6 to 8, to form a second covering layer on the particles covered with cerium hydroxide. The dispersion containing precursor particles was filtrated, and the precursor particles were washed with water and dried. A mass of the precursor particles was crushed to obtain the precursor particles.

The precursor particles were fired at a temperature of 500° C. for 2 hours, and then a mass of the particles was crushed with a hammer mill to obtain composite particles (C) having an average particle size of 0.25 μm. The titanium oxide content in the composite particles was 72 mass %, cerium oxide content was 10 mass %, and silicon oxide content was 18 mass %. Accordingly, the amount of cerium oxide per 100 parts by mass of titanium oxide was 13.9 parts by mass, and the amount of silicon oxide per 100 parts by mass of titanium oxide was 25.0 parts by mass.

### [Preparation of Pigment Composition]

### <Pigment Composition (B1)>

To 40 g of the obtained coating composition (A1) containing the fluorinated copolymer, 2.50 g of a methyl ethyl ketone dispersion (solid content concentration: 34.5%) of titanium oxide pigment (CR97, manufactured by Ishihara Sangyo Kaisha, Ltd., average particle size: 0.25 μm) was added, and further, 40 g of glass beads having a diameter of 1 mm were added, followed by stirring for 2 hours by a paint shaker. After the stirring, filtration was carried out to remove glass beads thereby to obtain a pigment composition (B1). This pigment composition (B1) was applied on a polyethylene terephthalate (PET) film at room temperature by potting, followed by air drying, and then heated and dried on a hot plate of 110° C. for 10 minutes to obtain a PET film having a thin film of the pigment composition (B1) formed on its surface. The visible light and UV transmittances of the obtained thin film were examined and found to be at most 2% within the entire range of from 200 to 800 nm.

### <Pigment Composition (B2)>

A pigment composition (B2) was obtained in the same manner as for the pigment composition (B1) except that instead of the coating composition (A1), the coating composition (A2) was used.

### <Pigment Composition (B3)>

A pigment composition (B3) was obtained in the same manner as for the pigment composition (B1) except that instead of the coating composition (A1), the coating composition (A3) was used.

<Pigment Composition (B1-a)>

A pigment composition (B1-a) was obtained in the same manner as for the pigment composition (B1) except that instead of the titanium oxide pigment (CR97, manufactured by Ishihara Sangyo Kaisha, Ltd., average particle size: 0.25 μm), the methyl ethyl ketone dispersion of the composite particles (C) (solid content concentration: 34%) was used.

### [Coating Composition]

### <Coating Composition (D1)>

To 40 g of the pigment composition (B1), 10 g of the coating composition (A1) was added and mixed to obtain a coating composition (D1).

### <Coating Composition (D2)>

A coating composition (D2) was obtained in the same manner as for the coating composition D1 except that instead of the pigment composition (B1), the pigment composition (B2) was used, and instead of the coating composition (A1), the coating composition (A2) was used.

### <Coating Composition (D3)>

A coating composition (D3) was obtained in the same manner as for the coating composition D1 except that instead of the pigment composition (B1), the pigment composition (B3) was used, and instead of the coating composition (A1), the coating composition (A3) was used.

<Coating Composition (D1-a)>

A coating composition (D1-a) was obtained in the same manner as for the coating composition D1 except that instead of the pigment composition (B1), the pigment composition (B1-a) was used.

<Coating Composition (D1-b)>

A coating composition (D1-b) was obtained in the same manner as for the coating composition D1 except that instead of the pigment composition (B1), the pigment composition (B1-a) was used, and 10 g of TINUVIN 384 and 3 g of TINUVIN 400, ultraviolet absorbers, manufactured by Ciba Specialty Chemicals were added.

<Coating Composition (D1-c)>

A coating composition (D1-c) was obtained in the same manner as for the coating composition D1 except that instead of the pigment composition (B1), the pigment composition (B1-a) was used, and 2.0 g of TINUVIN 384 and 0.6 g of TINUVIN 400, ultraviolet absorbers, manufactured by Ciba Specialty Chemicals were added.

<Coating Composition (D1-d)>

A coating composition (D1-d) was obtained in the same manner as for the coating composition D1 except that instead of the pigment composition (B1), the pigment composition (B1-a) was used, and instead of the coating composition (A1), 10 g of a diisopropylketone solution (solid content concentration: 6%) of a methyl methacrylate/butyl methacrylate copolymer (Catalogue No. 474029, manufactured by Aldrich, mass average molecular weight: 75,000) was added.

### Example

On one surface of PET films having a thickness of 50 μm, coating compositions (D1), (D1-a), (D1-b), (D1-c), (D1-d), (D2) and (D3) respectively were applied so that each film thickness became 20 μm, and they were dried at 80° C. for 1 hour. Folding properties and adhesion of the obtained double-layer sheets were evaluated. The results are shown in Table 1.

On the fluorine coating material-applied surface of each double-layer sheet, an EVA sheet having a thickness of 100 μm was laminated, and they were compressed under a load of 100 g/cm² at 150° C. The adhesion between the fluororesin layer and the EVA layer was evaluated, and the results are shown in Table 1.

### [Evaluation Methods]

Folding property evaluation 1: A double-layer structure sheet is folded to make an angle of 180° along a cylindrical mandrel having a diameter of 2 mm so that the applied surface faces outward, and fracturing of the coating film is observed. ◯ means a state of no fracture, and x means a state of fracturing.

Folding property evaluation 2: A double-layer structure sheet is folded so that the coating surface faces outward, and then it is left for 1 minute with a load of 50 g/cm² applied. Then the load is removed and the fracturing of the coating film is observed. ◯ represents a state of no fracture, and x represents a state of fracturing.

Adhesion evaluation: 100 squares having a width of 1 mm are cut in a coating film and a piece of cellophane tape is taped thereon, and the cellophane tape is removed to evaluate the adhesion of the coating film to the base. ◯ represents at least 91 squares adhered, Δ represents from 90 to 51 squares adhered, and x represents from 50 to 0 square adhered.

TABLE 1

| | Coating material composition | | | | | | |
|---|---|---|---|---|---|---|---|
| | D1 | D1-a | D1-b | D1-c | D1-d | D2 | D3 |
| Folding property | ◯ | ◯ | ◯ | ◯ | ◯ | X | ◯ |
| evaluation 1 | | | | | | | |
| Folding property | ◯ | ◯ | ◯ | ◯ | ◯ | X | ◯ |
| evaluation 2 | | | | | | | |
| Adhesion | ◯ | ◯ | ◯ | ◯ | ◯ | X | ◯ |
| (PET/fluororesin) | | | | | | | |
| Adhesion | ◯ | ◯ | ◯ | ◯ | ◯ | X | ◯ |
| (EVA/fluororesin) | | | | | | | |

### [Solar Cell Module 1]

On one surface of PET films having a thickness of 50 μm, via a polyester adhesive, coating compositions (D1), (D1-a), (D1-b), (D1-c), (D1-d), (D2) and (D3) respectively are applied so that the film thickness becomes 20 μm, and dried at 80° C. for 1 hour. On the side opposite to the coating film of each PET film, an EVA sheet having a thickness of 100 μm is laminated via a polyester adhesive, and they are compressed under a load of 100 g/cm² at 150° C. to prepare a back sheet. At the EVA side of this back sheet, a solar cell module having a structure wherein a solar cell, an EVA sheet and a glass plate are stacked is prepared.

### [Solar Cell Module 2]

On one surface of PET films having a thickness of 50 μm, via a polyester adhesive, coating compositions (D1), (D1-a), (D1-b), (D1-c), (D1-d), (D2) and (D3) respectively are applied so that the film thickness becomes 20 μm, and dried at 80° C. for 1 hour. Next, on the side where a coating film is applied, an EVA sheet having a thickness of 100 μm is laminated via a polyester adhesive, and they are compressed under a load of 100 g/cm² at 150° C. to prepare a back sheet. At the EVA side of this back sheet, a solar cell module having a structure wherein a solar cell, an EVA sheet and a glass plate are stacked is prepared.

### INDUSTRIAL APPLICABILITY

The present invention provides a back sheet for a solar cell module which is light in weight and excellent in productivity, wherein a coating film of the fluorinated copolymer (A) formed on at least one side of a substrate sheet is free from a problem of cracking, fracturing, whitening or peeling.

This application is a continuation of PCT Application No. PCT/JP2011/059306, filed Apr. 14, 2011, which is based upon and claims the benefit of priority from Japanese Patent Application No. 2010-095210 filed on Apr. 16, 2010. The contents of those applications are incorporated herein by reference in its entirety.

### EXPLANATION OF LETTERS OR NUMERALS

1: Solar cell

2: Sealing material layer

3: Surface layer

4: Substrate sheet

5: Coating film

6: Metal layer

7: Another polymer layer (for example, an EVA layer)

What is claimed is:

1. A back sheet for a solar cell module, comprising a substrate sheet and a coating film formed, on at least one side of the substrate sheet, from a coating composition which comprises a fluorinated copolymer (A) having repeating units derived from ethylene and repeating units derived from tetrafluoroethylene, and a solvent capable of dissolving the fluorinated copolymer (A) at a temperature of not higher than the melting point of the fluorinated copolymer (A).

2. The back sheet for a solar cell module according to claim 1, wherein the fluorinated copolymer (A) in the coating composition is one obtained by precipitating it from a solution having the fluorinated copolymer (A) dissolved in the solvent.

3. The back sheet for a solar cell module according to claim 1, wherein the proportion of repeating units derived from monomers other than tetrafluoroethylene and ethylene, is from 0.1 to 30 mol % in all repeating units in the fluorinated copolymer (A).

4. The back sheet for a solar cell module according to claim 1, wherein the fluorinated copolymer (A) is a fluorinated copolymer having crosslinkable groups.

5. The back sheet for a solar cell module according to claim 4, wherein the crosslinkable groups are at least one member selected from the group consisting of carboxy groups, acid anhydride groups and carboxylic halide groups.

6. The back sheet for a solar cell module according to claim 1, wherein, of the solvent, the dissolution index (R) for the fluorinated copolymer (A), based on Hansen solubility parameters and represented by the following formula (1), is less than 25:
R=4×(δd−5.7)²+(δp−5.7)²+(δh−4.3)² (1)
wherein δd, δp and δh represent the dispersion component, the polar component and the hydrogen bonding component, respectively, in Hansen solubility parameters, and their units are (MPa)^{1/2}, respectively.

7. The back sheet for a solar cell module according to claim 1, wherein the coating composition contains an ultraviolet absorber.

8. The back sheet for a solar cell module according to claim 1, wherein the coating composition contains a pigment.

9. The back sheet for a solar cell module according to claim 1, wherein a layer made of a polymer different from the coating film is provided on the outermost surface of the back sheet on the side to be in contact with a solar cell.

10. A process for producing a back sheet for a solar cell module, which comprises applying a coating composition having a fluorinated copolymer (A) having repeating units derived from ethylene and repeating units derived from tetrafluoroethylene, dissolved in a solvent capable of dissolving the fluorinated copolymer (A) at a temperature of not higher than the melting point of the fluorinated copolymer (A), on at least one side of a substrate sheet, followed by removing the solvent to form a coating film.

11. A solar cell module comprising, as sequentially laminated, a surface sheet, a sealing layer having a solar cell sealed by a resin, and the back sheet for a solar cell module as defined in claim 1.
